(19) United States
(12) Patent Application Publication
(10) Pub. No.: US 2025/0349752 A1
(43) Pub. Date: Nov. 13, 2025

(54) SEMICONDUCTOR PACKAGES AND METHODS OF MANUFACTURING THEREOF

(71) Applicant: Taiwan Semiconductor Manufacturing Company, Ltd., Hsinchu (TW)

(72) Inventor: Jen-Yuan Chang, Hsinchu (TW)

(73) Assignee: Taiwan Semiconductor Manufacturing Company, Ltd., Hsinchu (TW)

(21) Appl. No.: 19/279,237

(22) Filed: Jul. 24, 2025

Related U.S. Application Data
(63) Continuation of application No. 18/103,676, filed on Jan. 31, 2023.
(60) Provisional application No. 63/392,625, filed on Jul. 27, 2022.

(51) Int. Cl. H01L 23/00; H01L 21/78; H01L 23/58; H01L 25/065

(52) U.S. Cl. CPC H01L 23/562; H01L 21/78; H01L 23/585; H01L 24/08; H01L 25/0657; H01L 2224/08145; H01L 2225/06562; H01L 2225/06568

(57) ABSTRACT

A semiconductor device includes a first and second semiconductor chip having a respective first surface and a second surface opposite to each other. The semiconductor device can include a second semiconductor chip having a third surface and a fourth surface opposite to each other. The third surface of the second semiconductor chip can face the second surface of the first semiconductor chip. A first portion of a dielectric filling material can be in contact with a first sidewall of the first semiconductor chip. A second portion of a dielectric filling material can be in contact with a second sidewall of the second semiconductor chip. The first and second portions of the dielectric filling material can have a width that decreases in a corresponding increasing depth toward the first surface of the first semiconductor chip.

### CROSS-REFERENCE TO RELATED APPLICATION

This application is a continuation of U.S. patent application Ser. No. 18/103,676, filed Jan. 31, 2023, which claims priority to and the benefit of U.S. Provisional Application No. 63/392,625, filed Jul. 27, 2022, both of which are incorporated herein by reference in their entirety for all purposes.

### BACKGROUND

The semiconductor industry has experienced rapid growth due to continuous improvement in the integration density of a variety of electronic components (e.g., transistors, diodes, resistors, capacitors, etc.). For the most part, this improvement in integration density has come from repeated reductions in minimum feature size (e.g., shrinking the semiconductor process node towards the sub-nanometer node), which allows more components to be integrated into a given area. As the demand for miniaturization, higher speed, and greater bandwidth, as well as lower power consumption and latency has grown recently, there has grown a need for smaller and more creative packaging techniques for semiconductor dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is an example of a cross sectional view of semiconductor chips, in accordance with some embodiments.

FIG. 2 is an detail view of the semiconductor chips of FIG. 1, in accordance with some embodiments.

FIG. 3 is an example of a cross sectional view of semiconductor chips disposed over a carry wafer, in accordance with some embodiments.

FIG. 4 is an example of a second layer semiconductor chip over a first layer semiconductor chip, in accordance with some embodiments.

FIG. 5 is an example flow chart of a method for fabricating a semiconductor device, in accordance with some embodiments.

FIGS. 6, 7, 8, 9, and 10, illustrate cross-sectional views of example semiconductor devices during various fabrication stages, made by the method of FIG. 5, in accordance with some embodiments.

FIGS. 11a, 11b, 11c, and 11d illustrate top views of example semiconductor devices during various fabrication stages, made by the method of FIG. 5, in accordance with some embodiments.

FIGS. 12, 13, 14, and 15 illustrate cross-sectional views of example semiconductor devices during various fabrication stages, in accordance with some embodiments.

FIGS. 16a, 16b, and 16c are examples of three-dimensional integrated circuit (3DIC) semiconductor devices, in accordance with some embodiments.

FIG. 17 is an example of a three-dimensional integrated circuit (3DIC) semiconductor device, in accordance with some embodiments.

FIG. 18 is another example of a three-dimensional integrated circuit (3DIC) semiconductor device, in accordance with some embodiments.

FIG. 19 is yet another example of a three-dimensional integrated circuit (3DIC) semiconductor device, in accordance with some embodiments.

FIG. 20 is a multi-chip semiconductor device including at least one three-dimensional integrated circuit (3DIC), in accordance with some embodiments.

FIG. 21 is a multi-chip semiconductor device including at least one three-dimensional integrated circuit (3DIC), in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. References to “or” may be construed as inclusive so that any terms described using “or” may indicate any of a single, more than one, and all of the described terms.

As semiconductor technologies further advance, packaged semiconductor devices, e.g., three-dimensional integrated circuits (3DICs), have emerged as an effective alternative to further reduce the physical size of semiconductor devices. In a packaged (e.g., stacked) semiconductor device, active circuits such as logic, memory, processor circuits, and the like are fabricated on different semiconductor wafers or dies. Two or more these semiconductor chips may be installed side-by-side or stacked on top of one another to further reduce the form factor of the semiconductor device.

A dielectric material such an encapsulant can be formed over a plurality of semiconductor chips. The encapsulant can mechanically fix the semiconductor dies, such as for various processing steps or applications thereof. The encapsulant can further provide thermal sinking for one or more semiconductor dies. For example, the encapsulant can provide a thermal interconnection between a high power chip such as a logic chip and a low power chip such as a memory die. The encapsulant can form a thermal or mechanical junction with a heatsink, or other semiconductor packaging material. A distance between various semiconductor chips can vary along a z-axis of the device. For example, a die saw or plasma etch to separate or define the sidewalls of one or more semiconductor chips can be anisotropic such that upon a wafer or die flip, an upper portion of a sidewall can be sloped outward such that a sidewall extends laterally further as the z-axis is traversed in a downward direction. The boundary formed between one or more such chips can be wider at a base than at an upper surface. A dielectric can be deposited from the upper surface. However, according to some dielectric deposition methods, the relatively narrow opening between the chips can lead to an accumulation of stress in the dielectric material, such as by the forming of voids based on a blocking of a lower portion of an inter-chip gap by an upper portion thereof. The voids can lead to a reduction in thermal conductivity. The voids and other stress can lead to dielectric cracking which can further impact a thermal conductivity or reduce an insulation between chips or a mechanical fixing of the chips.

The present disclosure is directed to defining a profile of a chip, such as an inner chip of a 3DIC for a semiconductor device. The profile can reduce cracking of a dielectric material encapsulating the chip. The profile can be defined according to a die saw profile or an etch process. For example, a profile of an interconnect portion of the chip can be defined according to a first plasma etch process and a profile of a substrate portion of the chip can be defined according to a second plasma etch process. The plasma etch process can be isotropic or anisotropic according to an orientation of the semiconductor device while forming a dielectric. The plasma etch can define the profile of the sidewall of the chips such that an inter-chip spacing can be wider at a direction from which the dielectric material will be introduced. Each semiconductor chip can include a seal ring which can be disposed within a lateral boundary of a seal ring of a vertically adjacent chip. The various chips can be bonded according to a hybrid or fusion bonding process such that any number of vertically or horizontally spaced chips can form a multi-chip device which can be incorporated into a semiconductor device which includes one or more additional active or passive devices. Surface roughness or sharp edges of the semiconductor devices can be reduced to reduce stress formed in the dielectric. For example, an etching process can result in a minimum radius of about 1 nm for one or more features of the semiconductor device, which may further reduce cracking of a dielectric material.

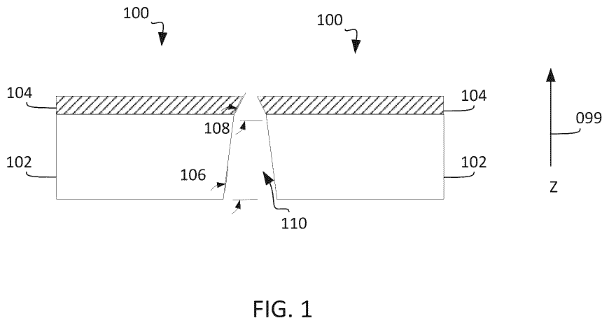

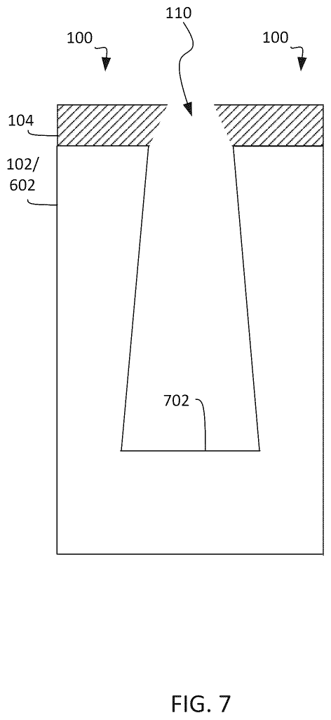

Referring to FIG. 1, depicted is a detail view of semiconductor chips 100. The semiconductor chips 100 can be diced from a semiconductor wafer. For example, the semiconductor chips 100 can be diced by a die saw to form an inter-chip spacing 110. The dimensions or profile of the inter-chip spacing 110 can be adjusted by one or more etching processes, as are further discussed with regard to, for example, FIG. 7. The spacing or profile of the inter-chip spacing 110 can be consistent for one or more edges of the semiconductor chips 100. For example, a semiconductor chip 100 having four laterally facing sides can have a same profile for each of the laterally facing sides, or each of the laterally facing sides to adjoin another semiconductor chip 100.

Each semiconductor chip 100 includes a substrate portion 102 and an interconnect portion 104, such as an oxide portion. The substrate portion 102 can be or include monocrystalline silicon, such as a monocrystalline silicon diced or otherwise derived from a monocrystalline silicon wafer. The substrate portion 102 can be or include intrinsic silicon or can include through silicon vias (TSV), or dopants such as n-type or p-type dopants. For example, a surface of the substrate portion 102 can include n-wells and p-wells for integrated circuits. The n-wells and p-wells can be joined along the surface of the substrate, or via the interconnect portion 104. For example, the interconnect portion 104 can include metallization layers interconnecting the surface of the substrate portion 102. The interconnect portion 104 can include through oxide vias (TOV) to interconnect the layers of the interconnect portion 104 or to connect to connector structures such as via structures, bumps, or wire landing pads. Each layer of the interconnect portion 104 can include a dielectric material such as un-doped silicon glass, a low-k or extreme low-k dielectric, or silicon dioxide. The layers can be continuous or can be delimited by an etch stop layer such as Silicon Nitride, Silicon Carbide, or the like, a hardmask layer, or another material formed intermediate to the dielectric layers.

The profiles of the substrate portion 102 and the interconnect portion 104 can be sloped along a z-axis 099. For example, the substrate portion 102 can taper according to a first angle 106 such that the width of the inter-chip spacing 110 between the substrate portions 102 of the respective semiconductors chips 100 reduces along the z-axis 099. The interconnect portion 104 can taper according to a second angle 108 such that the width of the inter-chip spacing 110 between the interconnect portions 104 of the respective semiconductors chips 100 reduces along the z-axis 099. The first angle 106 can be equal to the second angle 108, greater than the second angle 108, or less than the second angle 108. The first angle 106 or the second angle 108 can be less than 90°. Thus, the profile of the inter-chip spacing 110 can monotonically decrease along the z-axis 099 (e.g., traversing in the positive z-axis 099 or negative z-axis 099). The profile can be applied to each face of the semiconductor chip 100 which is generally parallel to the z-axis 099. Such angles can be selected to avoid or reduce cracking along a lateral edge of the depicted semiconductor chips 100.

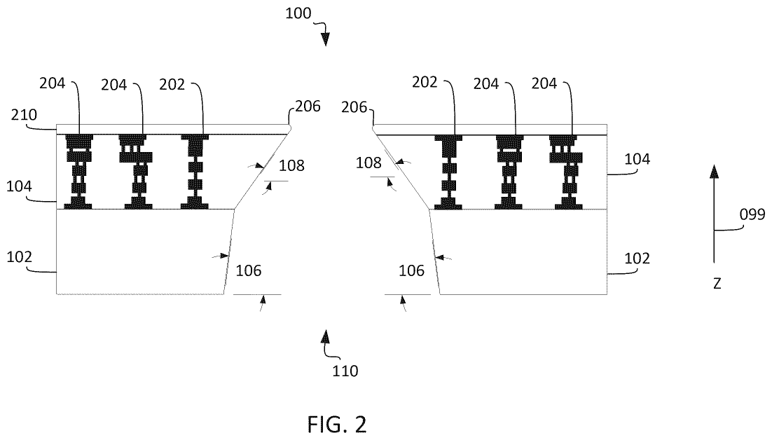

FIG. 2 illustrates a further detailed view of the semiconductor chips 100 of FIG. 1. The substrate portion 102 is shown having the first angle 106. The interconnect portion 104 is shown having the second angle 108, and in greater detail. For example, the top chip edge 206 can have a radius of about 1 nm or greater. Other features of the semiconductor chip 100 can have a similar radius or other indicia of surface roughness. For example, a maximum cycle time of a plasma etch process can be adopted, and a corresponding minimum cycle count of the process can be increased to control a surface roughness of a sidewall of the semiconductor chip 100. For example, the top chip edge 206 can avoid a sharp edge which might induce stress in a dielectric filling material formed around the top chip edge 206 (e.g., because such stress may lead to cracking or other formations of voids or discontinuities within a dielectric interfacing with the top chip edge 206). One or more films 210 such as a fusion bonding film 210 or a hybrid bonding film 210 can be deposited over the upper surface of the semiconductor chip 100. The film 210 can include silicon oxynitride (SIOₓN_{y}) or silicon dioxide (SiO₂). The film 210 can bond the semiconductor chip 100 to another semiconductor chip 100 or to a carry wafer (not depicted). The radius of the top chip edge 206 can include a radius of the film 210 or the interconnect portion 104.

The interconnect portion 104 can include a seal ring 202 around a periphery of the semiconductor chip 100. For example, the depicted cross sectional view of the seal ring 202 can extend completely or substantially around a perimeter of the device. The interconnect portion 104 can include one or more conductive structures 204 electrically connecting a surface of the substrate portion 102 to a surface of the semiconductor chip 100. For example, the conductive structures 204 can interconnect the substrate portion 102 or pads thereof, or connect the substrate portion 102 or pads thereof to a terminal of the semiconductor chip 100 such as a bump or ball. For example, the bump or ball con be configured to connect the chip to another element of a semiconductor device, such as another semiconductor chip 100 having an active surface, an integrated passive device (IPD), an interposer, or another element of a multi-chip die, such as a terminal to connect the device to a printed circuit board (PCB).

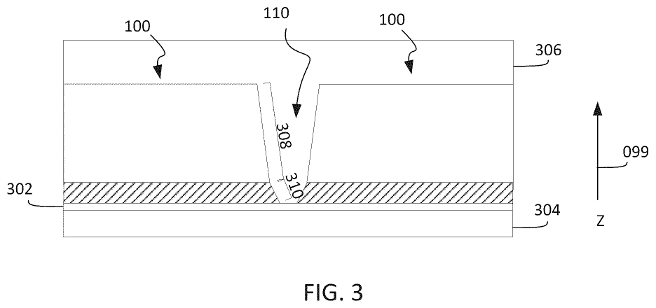

FIG. 3 illustrates two semiconductor chips 100 disposed over a carry wafer 304. The semiconductor chips 100 can be from a same wafer or a different wafer. For example, the semiconductor chips 100 can be picked from separate wafers for placement on the carry wafer 304. The semiconductor chips 100 can be a same type of semiconductor chip 100, or different types of semiconductor chips 100. For example, the semiconductor chips 100 can include one or more logic chips, memory chips, or sensor chips.

The semiconductor chips 100 can be placed on the carry wafer 304 separated by an intermediate material 302. The intermediate material 302 can be a same material as the film 210. For example, the intermediate material 302 can be a fusion bonding film 210. The semiconductor chips 100 can be inverted relative to the semiconductor chips 100 of FIG. 1. For example, the semiconductor chips 100 can be flipped prior to placement onto the carry wafer 304, or subsequent to placement on the carry wafer 304. The profile of the inter-chip spacing 110 is thus inverted. The inter-chip spacing 110 can have a width which reduces as the z-axis 099 is transited in the negative z direction (e.g., a “V” or “U” shaped inter-chip spacing 110). A first portion of the sidewall of the semiconductor chip 100 can have a first slope 308, and a second portion of the sidewall of the semiconductor chip 100 can have a second slope 310. The second slope 310 can be different than the first slope 308. For example, the first slope 308 can be greater than the second slope 310. According to various embodiments, the relative steepness of the first slope 308 and second slope 310 may reduce cracking of a dielectric disposed there-along. For example, a slope may define a decreasing inter-chip spacing 110 rate of reduction, which may avoid a formation of voids or stress that can lead to cracking.

A dielectric filling material 306 can be deposited into the inter-chip spacing 110. The dielectric filling material 306 can be deposited from an upper surface, such as by a chemical vapor deposition (CVD) process. The first slope 308 and the second slope 310 can reduce voids or stress accumulation in the dielectric material. For example, the relatively smaller width of the inter-chip spacing 110 can be filled with the dielectric filling material 306 in advance of the relatively wider portions of the inter-chip spacing 110. The reduced surface roughness of the features of the semiconductor chip 100 can further reduce the accumulation of stress or voids in the dielectric filling material 306.

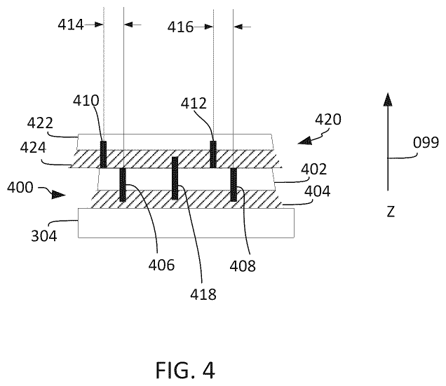

FIG. 4 illustrates a second layer semiconductor chip 420 placed over a first layer semiconductor chip 400. Each of the first layer semiconductor chip 400 or second layer semiconductor chip 420 can be or be derived from the semiconductor chips 100 of FIGS. 1-3. For example, the first layer semiconductor chip 400 and second layer semiconductor chip 420 can be derived from a same or different semiconductor wafer (e.g., silicon wafer). Although not depicted, merely for the clarity of FIG. 4, one or more intermediate layers can be intermediate to the first layer semiconductor chip 400 and the second layer semiconductor chip 420; intermediate to the first layer semiconductor chip 400 and the carry wafer 304; or over the upper surface of the second layer semiconductor chip 420. One or more connection structures such as bump structures or bumpless bonds can be disposed intermediate to the first layer semiconductor chip 400 and the second layer semiconductor chip 420. For example, the connection structures can be configured to integrate (e.g., bond) the first layer semiconductor chip 400 or the second layer semiconductor chip 420 to each other, or to a carry wafer 304. For example, the bond can be hybrid bonding, fusion bonding, direct bonding, dielectric bonding, metal bonding, solder joints (e.g., microbumps), or the like.

The connection structures can include one or more copper interconnects such as a TSV 418 to interconnect the respective semiconductor chips 100, 400, 420. For example, the TSV 418 can be configured to electrically interconnect circuits of the interconnect portion 404, 424 of the respective semiconductor chips 400, 420 or mechanically bond one or more chips or wafers following a bonding process. Further connection structures can be disposed along the upper surface of the substrate portion 422 of the second layer semiconductor chip 420. For example, the connection structures can be configured for temporary connection (e.g., to a carry wafer 304) or permanent connection (e.g., according to a bonding process such as a hybrid bonding, fusion bonding, direct bonding, dielectric bonding, metal bonding, solder joints (e.g., microbumps), or the like).

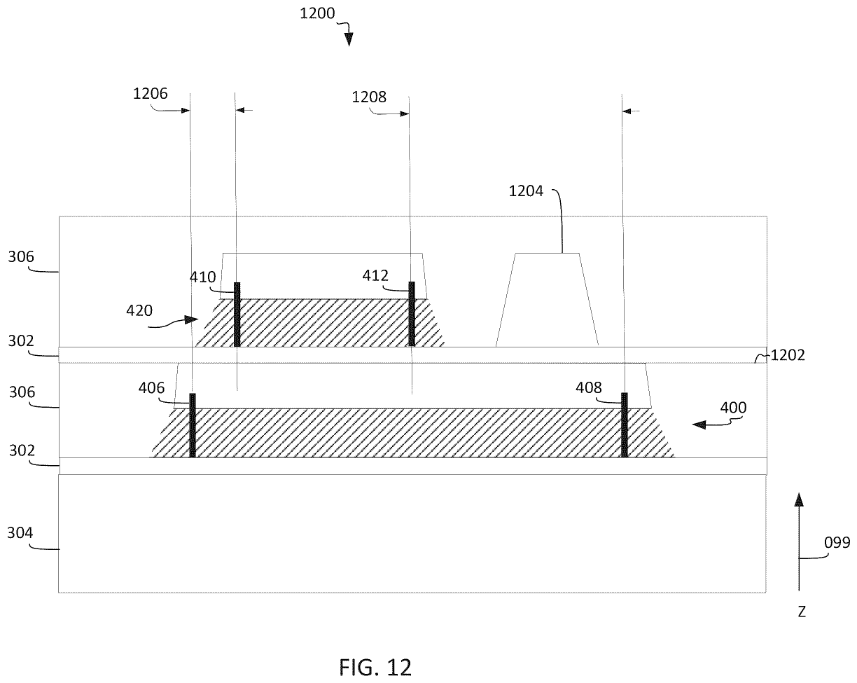

The interconnect portion 404 of the first layer semiconductor chip 400 faces the carry wafer 304, as depicted in FIG. 4. The interconnect portion 424 of the second layer semiconductor chip 420 faces the substrate portion 402 of the first layer semiconductor chip 400. Such a structure can be referred to as a face-to-back (F2B) orientation, whereas the ‘face’ refers to a surface of the interconnect portion 404 and the ‘back’ refers to the surface of the substrate portion 402. In some embodiments, semiconductor chips 100 can be arranged according to other structures. For example, semiconductor chips 100 can be arranged in face-to-face (F2F) orientations or back-to-back (B2B) orientations. For example, the first layer semiconductor chip 400 and the second layer semiconductor chip 420 can be F2F or B2B oriented, or a further semiconductor chip 100 (e.g., a third layer semiconductor chip 100) can be F2F or B2B oriented with respect to the first layer semiconductor chip 400 or the second layer semiconductor chip 420. As described herein, the semiconductor chip 100 refers to the semiconductor chip in isolation; other references to semiconductor chips such as the first layer semiconductor chip 400, second layer semiconductor chip 420, and so on can refer to one or more semiconductor chips employed in a semiconductor device (e.g., can contain same or different circuits, be derived form same or different wafers, or be of same or different dimension). Further, as is illustrated by FIGS. 12-18, multiple semiconductor chips 100 can be disposed laterally over a semiconductor chip 100.

The depicted cross section of the first layer semiconductor chip 400 includes leftmost seal ring portion 406 and a rightmost seal ring portion 408. The depicted cross section of the second layer semiconductor chip 420 can include a leftmost seal ring portion 410 and a rightmost seal ring portion 412. The depicted seal ring portions 406, 408, 410, 412 can be a portion of a substantially contiguous metal seal ring surrounding the perimeter of one or more semiconductor chips 400, 420. All or a portion of the seal ring of the second layer semiconductor chip 420 can overhang the seal ring of the second layer semiconductor chip 420. For example, an overhang distance 414 is depicted, as defined by the lateral distance between seal ring of the first layer semiconductor chip 400, having a perimeter, and a seal ring of the second layer semiconductor chip 420 outside the perimeter. All or a portion of the seal ring of the second layer semiconductor chip 420 can be disposed laterally within a perimeter of the seal ring of the first layer semiconductor chip 400. For example, an overlap distance 416 is depicted as defined by the lateral distance between seal ring of the first layer semiconductor chip 400, having a perimeter, and a seal ring of the second layer semiconductor chip 420 within the perimeter. The overhang distance 414 or the overlap distance 416 can be zero, positive, or negative. For example, the overhang distance 414 can be equal to or less than zero or less than about −1 μm. The overlap distance 416 can be equal to or greater than zero or greater than about 1 μm. According to the various positions of the first layer semiconductor chip 400 and the second layer semiconductor chip 420, cracking of a dielectric disposed there over may be reduced or eliminated. For example, the combinatorial slope of the sidewalls of the first layer semiconductor chip 400 and the second layer semiconductor chip 420 can avoid an accumulation of stress or voids in a dielectric formed along a sidewall of a semiconductor device comprising the first layer semiconductor chip 400 and the second layer semiconductor chip 420.

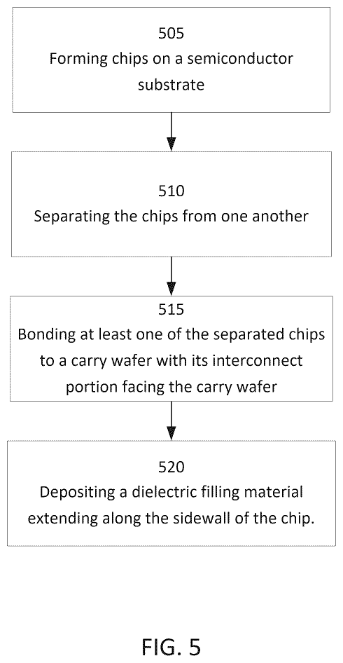

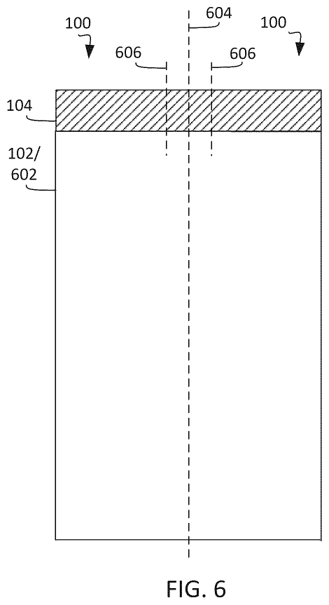

FIG. 5 illustrates a flow chart of an example method 500 for forming a semiconductor device, in accordance with various embodiments of the present disclosure. It should be noted that the method 500 is merely an example, and is not intended to limit the present disclosure. Accordingly, it is understood that the order of operation of the method 500 of FIG. 5 can change, that additional operations may be provided before, during, and after the method 500 of FIG. 5, and that some other operations may only be described briefly herein. Such a semiconductor device, made by the method 500, may include one or more components, as discussed with respect to FIGS. 6-13. Accordingly, operations of the method 500 will sometimes be discussed in conjunction with FIGS. 6-13, as illustrative examples.

The method 500 starts with operation 505 of forming semiconductor chips 100 on a semiconductor substrate. For example, the chips can be formed on an upper active surface the substrate portion 102 of FIG. 6, and an interconnection portion 104 can be connected thereto. For example, the method 500 can include forming an active surface along an upper surface of the semiconductor substrate. A series of metallization layers can be formed over the active surface. The metallization layers, along with a dielectric body encapsulating the metal can be referred to as an interconnect portion of the semiconductor device. A first metallization layer (which is sometimes referred to as a zeroth layer, or MO) can include one or more terminal pads to electrically connect a portion of the semiconductor device (e.g., a p-well, n-well, or gate thereof) to further layers of the semiconductor device. An alternating series of via structures vertically connecting the layers of the semiconductor device and lateral conductive structures laterally connecting portions of the semiconductor device can be formed. Each layer can include a dielectric portion, encapsulating the metals of the layer. The dielectric portion can be formed prior to or subsequent to forming the metal portions. For example, a metal can be deposited in openings formed in the dielectric layer (e.g., the dielectric filling material 306 of FIG. 3), or a dielectric material can be formed in openings formed in the metal. An intermediate layer such as an etch stop layer can separate the layers of the interconnect portion (e.g., the interconnect portion 104 of FIGS. 1-3).

The semiconductors can include one or more TSV 418. For example, the silicon can be etched by a directional etch to form an opening (e.g., a vertical, anisotropic etch, such as a Bosch process, one example of which is further described with respect to FIG. 7). An oxide can be deposited over the TSV 418 to avoid diffusion between the substrate and a metal. For example, a CVD process (e.g., atomic layer deposition) can be employed to interface the oxide with the TSV 418 sidewalls. A subsequent process can fill the opening with a metal. For example, an ALD process can seed the opening with the metal, and a subsequent plating (e.g., electro-plating) and chemical or mechanical grinding or polishing (CMG/P) process can fill the opening and plane an upper surface of the semiconductor device, respectively. The TSV 418 can be connected to terminal pads at the active surface of the substrate of the semiconductor device, or a layer of the interconnect portion 104 of the semiconductor device. Thus, the TSV 418 can be electrically connected to one or more signals of the semiconductor device, such that the bonding of operation 515 can electrically connect circuits disposed on vertically spaced semiconductor chips 100. For example, the TSV 418 can connect directly with copper pillars, micro bumps, or other intermediate connectors.

The method 500 continues to operation 510 of separating the semiconductor chips 100 from one another. For example, FIG. 7 depicts an example separation of semiconductor chips 100 by an inter-chip spacing 110. The chips can be separated by any combination of cutting, etching or grinding processes. For example, a die saw can separate all or a portion of the semiconductor chips 100. In additional to or instead of the die saw, the chips can be separated by an etching process such as a wet or dry (e.g., plasma etch). For example, a plasma etch process can form a ‘V’ or ‘U’ shaped separation between adjacent semiconductor chips 100. A plasma etch process can vary between the substrate portion 102 and the interconnect portion 104, such as by sequencing the etching processes according to an upper surface of the semiconductor device, or masking the substrate portion 102 or the interconnect portion 104 (e.g., by selectively applying an etch stop layer to one of the substrate portion 102 or the interconnect portion 104).

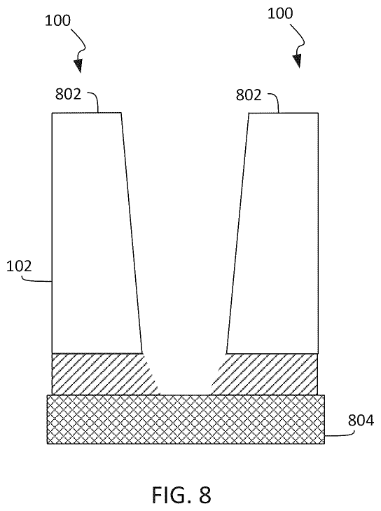

In some embodiments, the etching or sawing operation can completely separate the semiconductor chips 100 from one another. In some embodiments, the etching or sawing operation can partially separate the semiconductor chips 100 from one another, as depicted by FIG. 7. For example, the die saw can separate a first vertical portion of the wafer and not a second portion of the wafer, such that the semiconductor chips 100 can be moved, flipped, or otherwise processed as a wafer having a side of the one or more semiconductor chips 100 exposed. For example, FIG. 8 depicts flipped semiconductor chips 100 on a die tape, which can be disposed over a frame such as a source die frame. Operation 510 may be understood according to the inversion of the semiconductor chips 400, 420 between FIG. 7 and FIG. 8, such as the depicted die tape 804, and frame thereof. A subsequent die (e.g., wafer) grinding operation can remove the second vertical portion to complete the separation of the semiconductor chips 100. The die grinding operation can expose one or more TSV 418, such that the TSV 418 (or an intermediate connector applied thereto) can be connected to a further semiconductor chip 100 (e.g., a separated chip or a chip of a wafer).

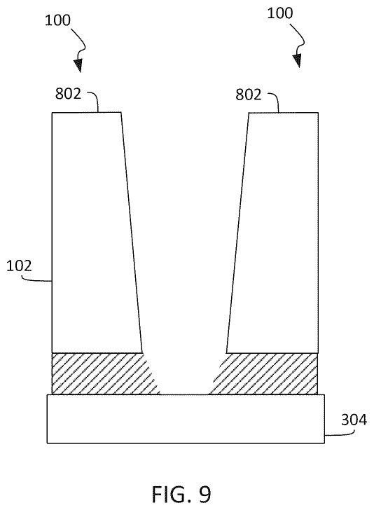

The method 500 continues to operation 515 of bonding at least one of the separated chips to a carry wafer 304 with its interconnect portion 104 facing the carry wafer 304. As is further discussed with regard to, for example, FIG. 9, and FIG. 12, the separated chips can be connected to the carry wafer 304 by a die tape, fusion bonding film 210, laser de-bondable film 210, vacuum, or other mechanical interface. The separated chips can be placed relative to one or more chip alignment marks of the carry wafer 304. In some embodiments the chips can be placed or bonded to the carry wafer 304 subsequent to their separation. For example, the die grinding process of operation 510 can be performed after placement of the chips on the wafer. For example, a fusion bond between the carry wafer 304 and the separated chips can resist a displacement of the separated chips during the grinding process.

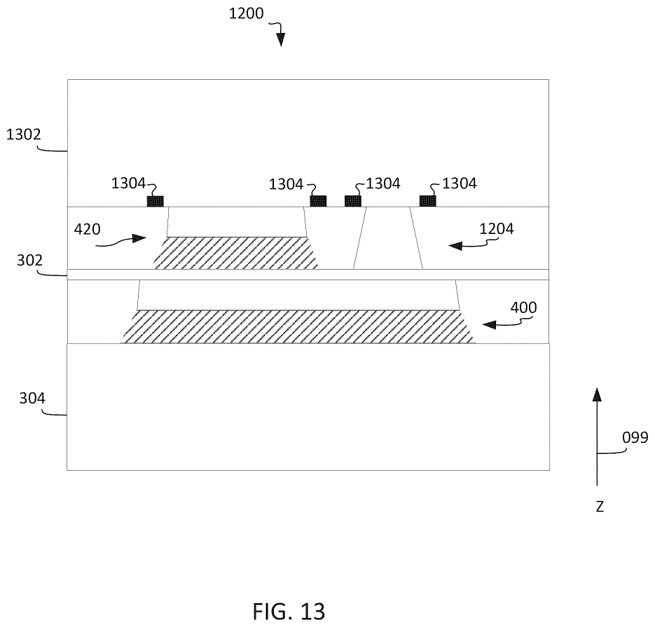

As is further described with reference to the semiconductor chips 400, 420, 1204 of FIG. 13, a semiconductor device 1200 can include semiconductor chips 400, 420, 1204 in various relative orientations. For example, in some embodiments, the semiconductor chip 400, 420 is connected to the carry wafer 304 with its interconnect portion 104 facing the carry wafer 304. The interconnect portion 104 and the substrate portion 102 of the semiconductor chip 100 can collectively form a sidewall of the chip. The sidewall can be defined by a separation operation such as the sawing or etching of operation 505. For example, the sidewall and a corresponding portion of a surface of the carry wafer 304 overlaid by the at least one separated chip can form an angle less than 90 degrees. Sub-operations of operation 505, like other operations of the method 500, can be performed at various times. For example, a sawing operation can separate the chips, which can thereafter be bonded to the carry wafer 304. An etching operation can thereafter further separate the chips to define a profile of the sidewall.

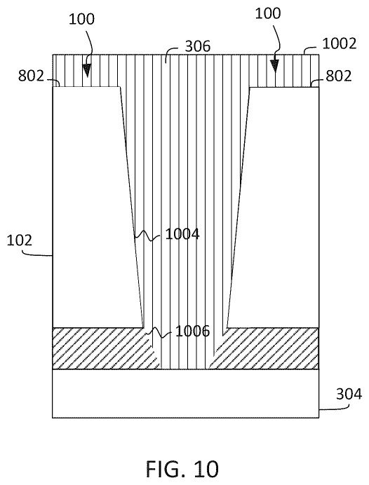

The method 500 continues to operation 520 of depositing a dielectric filling material 306 extending above the sidewall of the chip. FIG. 10 depicts an example of such a deposition of the dielectric filling material 306 along the sidewalls of the semiconductor chips 100. For example, a deposition operation can form a dielectric in an inter-chip spacing 110. In some embodiments, a single deposition operation can deposit the dielectric filling material 306. In some embodiments, a series of operations can form the deposit the dielectric filling material 306, or otherwise form a dielectric layer. For example, a dielectric layer can be formed above each constituent chip of a 3DIC package. At least the portion of the dielectric filling material 306 extending above the sidewall of the chip can be planarized, such as by a CMG/P operation. The dielectric filling material 306 along the sidewall may undergo lessor or reduced cracking according to the angles of the sidewalls according to the present disclosure.

Corresponding to operation 505, FIG. 6 illustrates two semiconductor chips 100 of a wafer 602 (e.g., a wafer 602 consisting essentially of the substrate portion 102, such as a silicon substrate). The interconnect portion 104 of the chip is formed by alternating deposition and removal of metal and dielectric materials. For example, a dielectric layer can have a photoresist selectively applied thereto by a mask and be etched to form openings which can be filled with metal, such as by a CVD process. The surface of the metal can thereafter be planarized by a CMG/P process. A further dielectric layer can be formed according to a CVD process, and may, in some embodiments, be leveled, such as according to a CMG/P process. Such processes can be alternated to form a desired number of layers.

A boundary line 604 can define a centerline for the two semiconductor chips 100 of the wafer 602. A further keep out line 606 can further define a portion of the substrate portion 102 or interconnect portion 104 which is reserved. For example, the keep out lines 606 can define a scribe line boundary for a dicing saw, or a region otherwise intended for removal, such as by one or more etchants (e.g., wet etchants or plasma etchants). A seal ring 202, such as a metal seal ring 202 (not depicted) can be formed for each of the two semiconductor chips 100 at a location beyond the keep out lines 606, relative to the boundary line 604. The seal ring 202 can extend around the lateral perimeter of each semiconductor chip 100 such that, according to a cross sectional view of the semiconductor chip, the seal ring 202 laterally bounds other structures of the semiconductor chips 100. For example, an active surface (e.g., a circuit) of the substrate portion 102 and interconnect portion 104 can be formed within a portion of the semiconductor chips 100 laterally delimited by the seal ring 202. One or more conductive structures can be disposed within the seal ring 202 (not depicted), such as to interconnect the active surface of the semiconductor chips 100 or to electrically, mechanically, or thermally connect to a connection structure such as a bump, ball, or via (e.g., a TSV 418 to connect to a vertically stacked semiconductor chip).

Corresponding to operation 510, FIG. 7 illustrates the two semiconductor chips 100 of FIG. 6, the semiconductor chips 100 having an inter-chip spacing 110 formed therebetween. For example, the semiconductor chips 100 can remain attached at a contagious portion 702 of the substrate portion 102 of the wafer 602. The noncontiguous portion of the substrate portion 102 can be separated, such as by a die saw or an etching operation. The profile of the substrate portion 102 or the interconnect portion 104 of the respective semiconductor chips 100 can be defined by the die saw, or an etching operation. For example, a die saw can separate the semiconductor chips 100, and a subsequent one or more etching operations can define the profile of the respective semiconductor chips 100.

An interconnect etching operation (e.g., an oxide etching operation) can etch the interconnect portion 104. For example, the interconnect portion 104 can be etched prior to the separation of the substrate portion 102 or the substrate portion 102 can be selectively masked prior to etching the interconnect portion 104. The etching gas can include Fluorocarbon (CₓF_{Y}) based gas Cₓ, F_{y} at varying radio frequency (RF) power, such as between 0-3 kW. The temperature can range from 0°-500° C. The chamber magnetization can range from 1 mT to 10 T. The chamber conditions such as the temperature or RF power can affect the degree of isotropic etch observed (i.e., can define the profile of the sidewall of the interconnect portion 104). Further, the interconnect etching operation can be adjusted according to one or more dielectric materials of the interconnect portion 104. For example, one or more extreme low-k dielectrics can be etched according to a different etching gas or chamber condition.

A substrate etching operation (e.g., a silicon etching operation) can etch the substrate portion 102. For example, the substrate portion 102 can be etched prior to the formation of the interconnect portion 104 or the interconnect portion 104 can be selectively masked prior to etching the substrate portion 102. The etching process can be a Bosch process, which is selected to be at least somewhat isotropic or the etching process can be substantially anisotropic, and the plasma ion incidence angle can be adjusted to define the profile of the sidewall of the semiconductor chip. The etching gas can include Fluorocarbon (C_{X}F_{X}) based gasses or SF_{X}, (e.g., sulfur hexafluoride). The cycle count can vary from 0-1 million cycles. The cycle time can vary from 1 ms to 1000 seconds. The proportion of SF_{X} to C_{X}Y_{X}, the time for polymer formation (e.g., fluorocarbon polymers), can define a profile of the sidewall of the substrate portion 102. For example, increasing or decreasing a lateral etching of the sidewall can define a shallower or steeper profile of the sidewall, respectively. As has already been discussed (e.g., with regard to FIGS. 1-3) the steepness of the profile can cause or be associated with a reduction in cracking, relative to a vertical sidewall.

FIG. 8 illustrates the two semiconductor chips 100 of FIG. 7 inverted and placed over a die tape 804. In some embodiments, the semiconductor chips 100 can be placed on a fusion bonding film 210, laser de-bondable film 210 or other film 210 in addition to or instead of the die tape 804. As depicted, the semiconductor chips 100 are separated. Such separation can be performed by techniques further described by the description of FIG. 9, which may expose an upper surface 802 of the substrate. The inversion of the semiconductor chips 100 can cause the distance between the semiconductor chips 100 to reduce proximal to the die tape 804, such that cracking of a dielectric material formed there-over may be reduced or eliminated.

Corresponding to operation 515, FIG. 9 illustrates the semiconductor chips 100 placed over a carry wafer 304. The semiconductor chips 100 can be placed over the carry wafer 304, such as directly or subsequent to a transfer to a die frame such as to adhere a film to the semiconductor chips 100. The film or another intermediate material can be configured to bond the semiconductor chip 100 to another semiconductor chip 100 or to a carry wafer 304. The substrate portion 102 can be thinned, such as by grinding the wafer. The grinding can remove a contagious portion of the substrate portion 102, or expose one or more hybrid bonding contacts, such as copper contacts (not depicted). For example, the grinding can expose an upper surface 802 of the substrate, which may expose a copper contact embedded in the substrate.

Corresponding to operation 520, FIG. 10 illustrates a dielectric filling material 306 deposited over the semiconductor chips 100. The dielectric filling material 306 can extend along a sidewall of the chips. The sidewall-chip junction can comprise a first sidewall junction portion 1004 at a first angle 106, and a second sidewall junction portion 1006 at a second angle 108, different than the first angle 106. The dielectric filling material 306 can be deposited according to a CVD process and thereafter leveled to establish a dielectric upper surface 1002, or deposited according to other techniques or methods. The dielectric filling material 306 may exhibit reduced cracking or voids, relative to dielectric filling material 306 formed over semiconductor chips 100 having vertical sidewalls. The dielectric upper surface 1002 or a portion thereof can extend above the substrate upper surface 802, or be shared therewith.

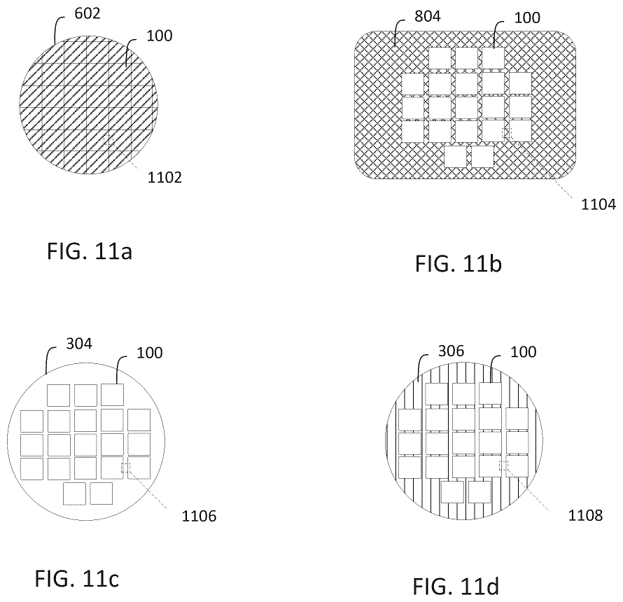

FIGS. 11a, 11b, 11c, and 11d illustrate a top view of semiconductor chips 100 during various fabrication stages. Particularly, FIG. 11a depicts a top view of semiconductor chips 100 disposed along an upper surface of a wafer 602. For example, FIG. 11a can depict a top view corresponding to the cross sectional view of FIG. 6 or 7. A first cut line 1102 can depict a lateral portion of the semiconductor chips 100 of FIG. 6 or 7. FIG. 11b depicts a top view of flipped semiconductor chips 100 on a die tape 804, disposed over a frame. For example, FIG. 11b can depict a top view corresponding to the cross sectional view of FIG. 8. A second cut line 1104 can depict a lateral portion of the semiconductor chips 100 of FIG. 8. FIG. 11c depicts a top view of semiconductor chips 100 disposed over a carry wafer 304. For example, FIG. 11c can depict a top view corresponding to the cross sectional view of FIG. 9. A third cut line 1106 can depict a lateral portion of the semiconductor chips 100 of FIG. 9. FIG. 11d depicts a top view of semiconductor chips 100 disposed over a carry wafer 304. For example, FIG. 11d can depict a top view corresponding to the cross sectional view of FIG. 10. A fourth cut line 1108 can depict a lateral portion of the semiconductor chips 100 of FIG. 10.

FIG. 12 illustrates a semiconductor device 1200 according to some embodiments. An intermediate material 302 such as a hybrid bonding film 210 can separate the carry wafer 304 from the first layer semiconductor chip 400. For example, the intermediate material 302 can be intermediary to the carry wafer 304 and a first layer semiconductor chip 400. In some depictions of the present disclosure, one or more intermediate materials 302 may not be depicted for clarity of the figure. Such an omission is not intended to be limiting. For example, the semiconductor device 1200 can include multiple layers of intermediate materials 302 at one or more junctions. The intermediate material 302 can form an intermediate layer of one or more materials such as a fusion bonding film 210, hybrid bonding film 210, die attach film 210, or other layers for temporary or permanent bonding. For example, slide-off or laser de-bondable film 210 can be employed to temporarily attach a carry wafer 304. As depicted by the disclosure of FIG. 10, a dielectric filling material 306 can be deposited extending along the sidewall of the first layer semiconductor chip 400. One or more further layers comprising a dielectric filling materials 306 can be formed over one or more chips on various layers of a semiconductor device 1200. In some embodiments, the planing of the semiconductor device 1200 can reduce a thickness of the substrate portion of the semiconductor device 1200 to expose a metal pad for bonding with another layer of the semiconductor device 1200 (e.g., hybrid bonding). One or more further layers of intermediate materials 302 can be formed over the upper surface 1202. A second layer semiconductor chip 420 can be disposed over the further layers formed from an intermediate material 302. The second layer semiconductor chip 420 can be or be similar to the second layer semiconductor chip 420 of FIG. 4. A dummy chip 1204 consisting essentially of a semiconductor such as silicon can be disposed over the first layer semiconductor chip 400. The dummy chip 1204 can lack a seal ring, or an interconnect portion, or can include an interconnect portion having fewer layers than the first layer semiconductor chip 400 or the second layer semiconductor chip 420. For example, the dummy chip 1204 can route signals between connector structures or active surfaces of another semiconductor chip 100.

A dielectric filling material 306 can be formed (e.g., deposited) over the second layer semiconductor chips 420. The dielectric filling material 306 can be leveled to form a generally smooth upper surface thereof. The dielectric filling material 306 for the second layer of the semiconductor device 1200 can be a same dielectric filling material 306 as the first layer of the semiconductor device 1200, or can vary therefrom. In some embodiments, the dielectric filling material 306 can be formed over a plurality of layers of the semiconductor device 1200. For example, the dielectric filling material 306 for the first and second layers of the semiconductor device 1200 can be deposited following the placement of the second layer semiconductor chip 420 and the dummy chip 1204. For example, the intermediate materials 302 can be selectively formed over the first layer semiconductor chip 400 such that the dielectric filling material 306 can cover the sidewalls thereof. According to a sidewall geometry, cracking of the dielectric filling material 306 may be reduced along the various lateral edges of the semiconductor chips 400, 420, including the dummy chip 1204.

As depicted, the lateral seal ring portions 410, 412 (e.g., metal seal rings) of the second layer semiconductor chip 420 are disposed within (e.g., surrounded by) a lateral dimension of the seal ring lateral portions 406, 408 (e.g., metal seal rings) of the first layer semiconductor chip 400. For example, the lower left seal ring 406 extends laterally beyond the upper left seal ring 410 by a first distance 1206; the lower right seal ring 408 extends laterally beyond the upper right seal ring 412 by a second distance 1208. Although only one cross sectional plane is depicted, the upper seal ring can be bounded laterally by the lower seal ring. For example, the distance between the seal rings can be greater to or equal than zero (e.g., can be about 1 μm). The lateral distance between the lateral extremes of the first layer semiconductor chip 400 and the second layer semiconductor chip 420, or other adjacent vertical layers can be greater than or equal to zero (e.g., can be about 1 μm). The lateral displacement of chips of a same level, such as the second layer semiconductor chip 420 and the dummy chip 1204 can be greater than or equal to zero (e.g., can be about 30 μm).

FIG. 13 illustrates a bonding between the first layer semiconductor chip 400 and the second layer semiconductor chip 420 or the dummy chip 1204. The bonding of the semiconductor chips 400, 420, 1204 can be at wafer level. In such wafer-level bonding, wafers on which one or more of the semiconductor chips 400, 420, 1204 are formed, respectively, are bonded together, and are then sawed or plasma etched into chips. Alternatively, the bonding may be performed at a chip level. One or more semiconductor chips 400, 420, 1204 can be bonded onto a die. For example, the second layer semiconductor chip 420 or the dummy chip 1204 can be sawed or plasma etched and thereafter bonded to the first layer semiconductor chip 400 prior to the separation of the respective first layer semiconductor chip 400 from a wafer.

A first carry wafer 304 and second carry wafer 1302 can bound the semiconductor device 1200. The first carry wafer 304 and second carry wafer 1302 can receive semiconductor chips 100 such as the first layer semiconductor chip 400, the second layer semiconductor chip 420, and the dummy chip 1204. Each of the chips can be diced from a wafer or included on a wafer. In some embodiments, the carry wafers 304, 1302 can be of a greater thickness than the chips or wafers carried thereby. For example, the first carry wafer 304 and second carry wafer 1302 can be configured to apply a pressure to the first layer semiconductor chip 400 and the second layer semiconductor chip 420, such as in the presence of a pressure, vacuum, or temperature controlled environment (e.g., anneal), or the like. The bonding can be F2F, F2B, or B2B. For example, the interconnect portion 104 of at least one chip can face a carry wafer 304, 1302 thereof. Various carry wafers 304, 1302 can include die alignment marks 1304 to control a placement of a semiconductor chip 400, 420, 1204, or another device relative to the semiconductor chip 400, 420, 1204 (e.g., a connector terminal).

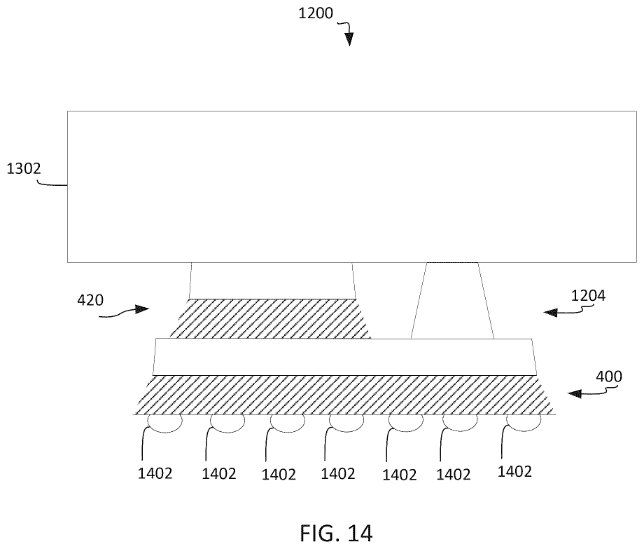

FIG. 14 illustrates a removal of one or more carry wafers, such as the removal of the first carry wafer 304 of FIG. 10. In some embodiments, the second carry wafer 1302 can be removed. The removal of the first carry wafer 304 can include a separation of a slide-off or laser de-bondable film 210 employed to attach the carry wafer 304 to the semiconductor device 1200. The removal of the first carry wafer 304 can reveal one or more connection pads or other conductive elements. For example, the conductive elements can be electrically connected to another connection pad or an active surface of one or more substrate portions 402, 422 of a semiconductor chip 400, 420. The conductive elements can be configured to attach to another semiconductor chip 100, such as another 3DIC, an interposer, or a single chip die. The conductive elements can be configured to receive a connector 1402 such as a micro bump, controlled collapse chip connection (C4) bump, other chip connection (C2) bump or pillar, or pad. The connecter 1402 can be configured to connect to another portion of a semiconductor device 1200 such as a semiconductor chip (e.g., another 3DIC), an interposer, or a single chip die.

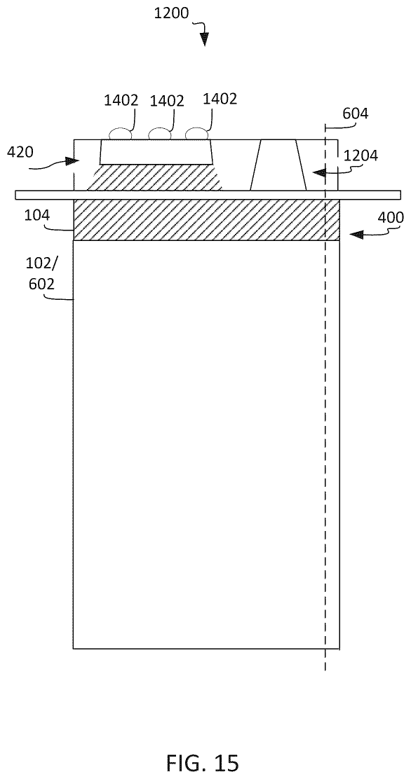

FIG. 15 illustrates an alternative embodiment of a semiconductor device 1200, relative to the embodiments disclosed by FIGS. 7-11d. For example, the first layer semiconductor chips 400 can be on a contiguous wafer 602, wherein each of the first layer semiconductor chips 400 are bounded by a boundary line 604. Diced chips such as a second layer semiconductor chips 420 or dummy chips 1204 can be attached to the wafer 602. The second layer semiconductor chips 420 and the first layer semiconductor chips 400 can be oriented in a F2F configuration. The second carry wafer 1302 can be removed to reveal one or more connection pads or other conductive elements to connect to another portion of a semiconductor device 1200, or to receive a connector 1402 on the upper surface of the semiconductor device 1200.

The features of FIG. 14 and FIG. 15 can be individually or combinatorically employed according to one or more embodiments. For example, in some embodiments, the connectors 1402 can be formed on the first layer semiconductor chip 400 (e.g., after thinning the wafer 602 connected thereto). Indeed, the various embodiments of this disclosure can be substituted with other embodiments disclosed herein, or which are known in the art.

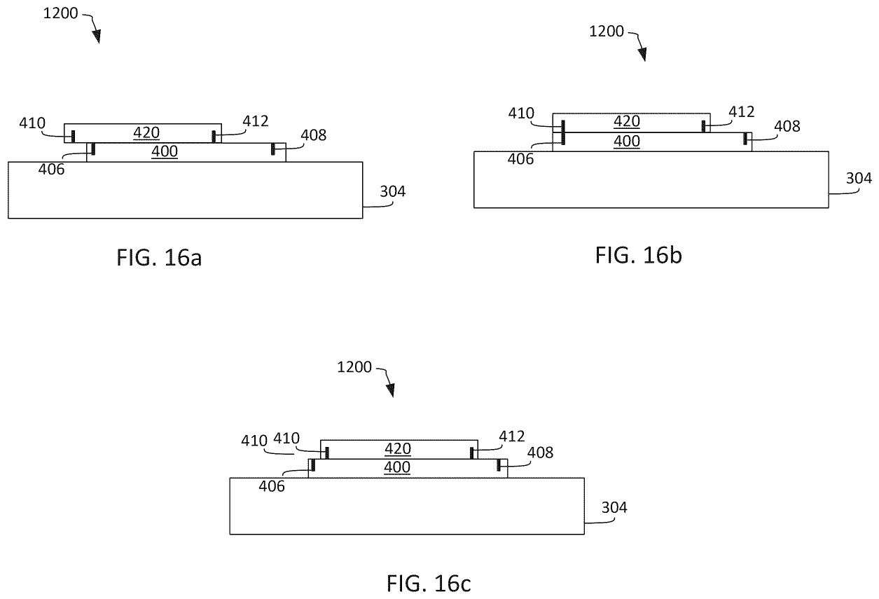

FIGS. 16a, 16b, and 16c depict various semiconductor devices 1200 having a first level semiconductor device 400 and a second level semiconductor chip 420 disposed over a carry wafer 304, according to some embodiments. The semiconductor devices 1200 include various lateral spacings between seal ring portions of vertically adjacent semiconductor chips 400, 420. Such spacings can be employed for further chips, such as a third layer semiconductor chip 100, an additional second layer semiconductor chip 420, and the like. Merely for brevity, FIGS. 16a, 16b, and 16c depict each of a rightmost edge of the first level semiconductor chip 400 and a rightmost seal ring portion 408 of the first level semiconductor chip 400 extending laterally beyond a rightmost seal ring portion 412 of the second level semiconductor chip 420. According to some embodiments various orientations of the rightmost seal rings 408, 412 or rightmost edges of the first layer semiconductor chip 400 and second layer semiconductor chip 420 can be adjusted similar to the left edges thereof.

Particularly, a chip edge alone or a seal ring and chip edge, in combination, of an upper level chip can extend beyond a lower level, as depicted in FIG. 16a wherein each of the leftmost edge of the second layer semiconductor chip 420 and the leftmost seal ring 410 thereof extend beyond each of the leftmost edge of the first layer semiconductor chip 400 (and the leftmost seal ring 406 thereof). A chip edge alone or a seal ring and chip edge, in combination, of an upper level chip can overlap a lower level chip, as depicted in FIG. 16b wherein each of the leftmost edge of the second layer semiconductor chip 420 and the leftmost seal ring 410 thereof overlap the leftmost edge of the second layer semiconductor chip 420 and the leftmost seal ring 406 thereof, respectively. A chip edge alone or a seal ring and chip edge, in combination, of a lower level chip can extend beyond an upper level, as depicted in FIG. 16c wherein each of the leftmost edge of the first layer semiconductor chip 400 and the leftmost seal ring 406 thereof extend beyond the leftmost edge of the second layer semiconductor chip 420 (and the leftmost seal ring 406 thereof). The chip edge profiles (e.g., sidewalls) may be formed to avoid cracking along each of the depicted embodiments.

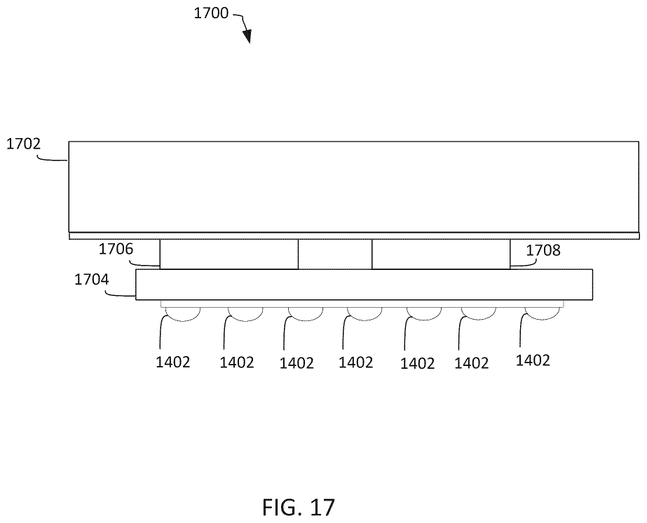

FIGS. 17 through 19 depict a series of example semiconductor devices 1700, 1800, 1900. For example, any of the depicted chips can be a dummy chip such as a spacer or interposer, or can contain circuits along a surface of a substrate portion thereof. The sidewalls of the various chips can have a vertical profile, an inwardly sloping profile or an outwardly sloping profile. The sidewall profile can vary between various portions of the chips, such as between a substrate portion and interconnect portion. The chips can be arranged in a F2F configuration, a F2B configuration, or a B2B configuration. For example, the multi-level devices can be formed from any combination of facings of respective interconnect portions thereof. Although not depicted, the seal rings of the devices disposed within the lateral extremes of the upper chips can be disposed within some or all of the lateral extremes of the seal rings of the lower chips. A carry substrate 1702 can be one of two carry substrates used to bond the various semiconductor chips 100 of the semiconductor devices 1700, 1800, 1900. The various semiconductor chips 100 can be mechanically thermally, or electrically connected by an encapsulant (e.g., a dielectric), or by a bond between various chips. The depicted devices are non-limiting; their features can be omitted, substituted, added, modified, or combined to form various 3DICs. Each lateral edge of each chip can interface with a dielectric. Each lateral edge (e.g., sidewall) can include a profile to reduce cracking of the dielectric. For example, first level semiconductor chips 400, second level semiconductor chips 420, or third level semiconductor chips 100 can include a sloped profile on interior and exterior facing sidewalls, as is depicted in, for example, FIG. 2.

Referring now to FIG. 17, an example cross sectional view of a semiconductor device 1700 is provided, according to some embodiments. A first semiconductor chip 1704 is connected to multiple connectors 1402. A second semiconductor chip 1706 and third semiconductor chip 1708 are disposed laterally within the extremes of the first semiconductor chip 1704. Although not depicted, the lateral extremes of the second semiconductor chip 1706 and third semiconductor chip 1708 can be disposed within in the lateral extremes of the first semiconductor chip 1704 in a plane perpendicular to the depicted plane. A carry substrate 1702 is connected to the second semiconductor chip 1706 and third semiconductor chip 1708.

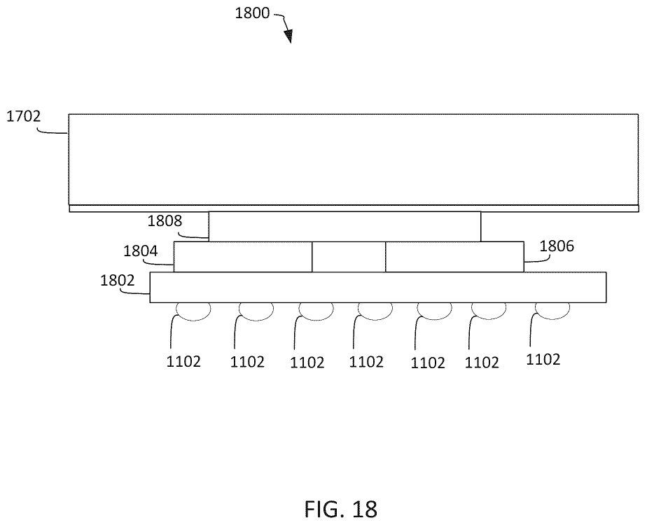

Referring now to FIG. 18, an example cross sectional view of a semiconductor device 1800 is provided, according to some embodiments. A first semiconductor chip 1802 is connected to multiple connectors 1402. A second semiconductor chip 1804 and third semiconductor chip 1806 are vertically stacked over the first semiconductor chip 1802. A fourth semiconductor chip 1808 is disposed over the second semiconductor chip 1804 and third semiconductor chip 1806. A spacing between the second semiconductor chip 1804 and third semiconductor chip 1806 can be between about 30 μm and about 500 μm. For example, the spacing can be about 50 μm.

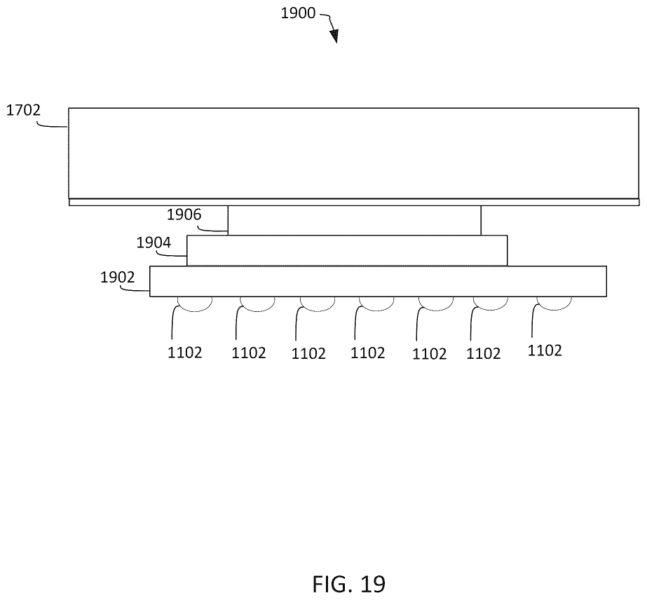

Referring now to FIG. 19, an example cross sectional view of a semiconductor device 1900 is provided, according to some embodiments. A first semiconductor chip 1902 is connected to multiple connectors 1402. A second semiconductor chip 1904 is laterally bounded by, and vertically stacked over the first semiconductor chip 1902. A third semiconductor chip 1906 is laterally bounded by, and vertically stacked over the second semiconductor chip 1904.

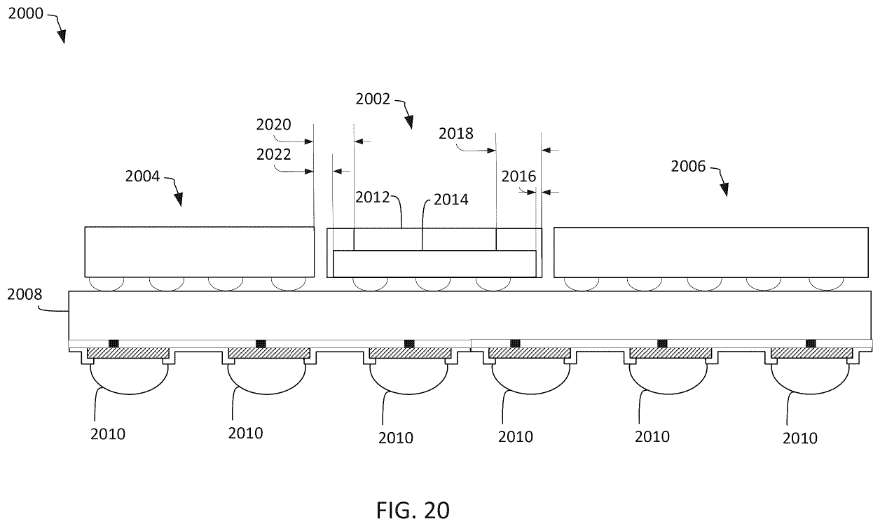

FIG. 20 depicts a semiconductor device 2000 including a 3DIC 2002 and other chips, according to some embodiments. The 3DIC 2002 can perform various functions (e.g., a logic die, such as a graphics, I/O, or processor die). The 3DIC 2002 can logically, thermally, mechanically, or electrically interface with one or more additional chips of the semiconductor device 2000. For example, the 3DIC 2002 can be bounded by a first monolithic chip 2004 and a second monolithic chip 2006. In some embodiments, the monolithic chips 2004, 2006 can be substituted for another 3DIC chip. The monolithic chips 2004, 2006 can be memory chips, IPDs, logic chips, RF chips, power delivery network chips, or the like. The 3DIC 2002 and one or more other chips 2004, 2006 can connect to an interposer 2008, which can form interconnections between the one or more chips 2002, 2004, 2006, or connect the one or more chips 2002, 2004, 2006 to a terminal connector 2010 such as a C2 ball. The connection to the terminal connector 2010 can include an intermediate connection such as under bump metallurgy layer (UBM).

The 3DIC 2002 includes a first semiconductor chip 2012 and a second semiconductor chip 2014. The 3DIC can also include a dielectric filling material 306 to define the lateral dimensions of the 3DIC 2002. For example, a distance 2018 between the first semiconductor chip 2012 and a lateral extreme of the 3DIC 2002 can be greater than about 1 μm (e.g., between about 10 μm and about 100 μm). A distance 2016 between the second semiconductor chip 2014 and a lateral extreme of the 3DIC 2002 can be greater than 1 about μm (e.g., between about 10 μm and about 100 μm). The distance 2018 between the second semiconductor chip 2014 and a lateral extreme of the 3DIC 2002 is depicted as larger than the distance 2016 between the second semiconductor chip 2014 and a lateral extreme of the 3DIC 2002. Such a depiction is not intended to be limiting. For example, the distances 2016, 2018 can be equal or either distance can be greater. According to the sidewall slopes disclosed herein, cracking may be avoided between the depicted 3DIC 2002, and the other chips 2004, 2006.

A distance 2020 between the first semiconductor chip 2012 and a lateral extreme of another chip 2004 laterally adjoining the 3DIC 2002 can be greater than about 30 μm (e.g., between about 50 μm and about 500 μm). A distance 2022 between the second semiconductor chip 2014 and a lateral extreme of another chip 2004 laterally adjoining the 3DIC 2002 can be greater than about 30 μm (e.g., between about 50 μm and about 500 μm). The dimensions can be defined according to a scribe line width, wherein a scribe line width can be defined according to a die saw or etching process, or an acceptable yield. For example, a narrow scribe line can be achieved according to a chip separation process or by rejecting chips failing to meet the defined scribe line.

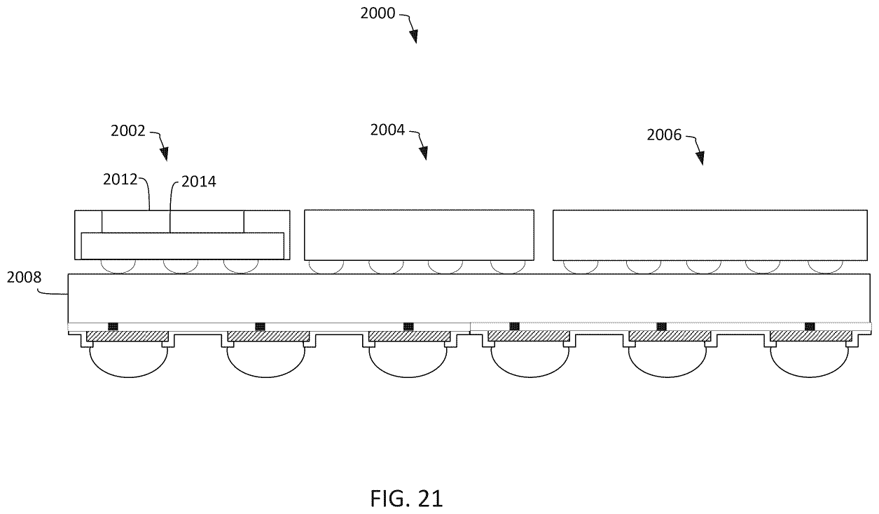

FIG. 21 illustrates a further depiction of a semiconductor device 2000, according to some embodiments. Such a depiction is provided merely to illustrate an example alternative embodiment, relative to FIG. 20, and is not intended to be limiting. As depicted, the 3DIC 2002 can be disposed along an edge of the semiconductor device 2000. According to some embodiments, the 3DIC 2002 can be disposed throughout a semiconductor device 2000 such as at another lateral position, or another vertical position (e.g., another layer of the semiconductor device 2000). For example, the 3DIC 2002 can be disposed over the other chips 2004, 2006, relative to the depiction of FIG. 20. Indeed, various embodiments, can include one or more 3DIC 2002 disposed in various locations thereof. According to the sidewall slopes disclosed herein, cracking may be avoided between the depicted 3DIC 2002, and the other chips 2004, or along an outer edge of the semiconductor device 2000.

In one aspect of the present disclosure, a semiconductor device is disclosed. The semiconductor device can include a first semiconductor chip having a first surface and a second surface opposite to each other. The semiconductor device can include a second semiconductor chip disposed above the first semiconductor chip. The semiconductor chip can include a third surface and a fourth surface opposite to each other. The third surface of the second semiconductor chip can face the second surface of the first semiconductor chip. A dielectric filling material can include a plurality of portions. A first one of the plurality of portions can be in contact with a first sidewall of the first semiconductor chip. A second one of the plurality of portions can be in contact with a second sidewall of the second semiconductor chip. The first and second portions of the dielectric filling material can have a width that decreases in a corresponding increasing depth toward the first surface of the first semiconductor chip.

In another aspect of the present disclosure, a semiconductor device is disclosed. The semiconductor device can include a first semiconductor chip. The first semiconductor chip can have a first surface and a second surface opposite to each other. The semiconductor device can include a second semiconductor chip disposed above the first semiconductor chip. The second semiconductor chip can be vertically bonded to the first semiconductor chip. The second semiconductor chip can include a third surface and a fourth surface opposite to each other. The third surface of the second semiconductor chip can face the second surface of the first semiconductor chip. The first semiconductor chip can include a first sidewall extending from the second surface to the first surface. A first angle between the first surface and the first sidewall can be less than 90 degrees. The second semiconductor chip can include a second sidewall extending from the fourth surface to the third surface. A second angle between the third surface and the second sidewall can be less than 90 degrees.

In yet another aspect of the present disclosure, a method for fabricating semiconductor devices is disclosed. The method can include forming multiple chips on a semiconductor substrate. The chips can share the same semiconductor substrate. The method can include separating the chips from one another. Each of the separated chips can include a corresponding portion of the semiconductor substrate and a corresponding interconnect portion. The method can include bonding at least one of the separated chips to a carry wafer with its interconnect portion facing the carry wafer. The corresponding portion of the semiconductor substrate and the corresponding interconnect portion of the separated chip can collectively form a sidewall. The sidewall and a corresponding portion of a surface of the carry wafer can be overlaid by the at least one separated chip to form an angle less than 90 degrees. The method can include depositing a dielectric filling material extending along the sidewall of the at least one separated chip.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first semiconductor chip having a front surface comprising a plurality of metallization layers formed over an active surface and a back surface of a semiconductive substrate, wherein opposing sidewalls of the first semiconductor chip, extending between the front surface and the back surface, taper to reduce a lateral dimension of the first semiconductor chip from the front surface to the back surface.

2. The semiconductor device of claim 1, wherein the taper of a first portion of the sidewalls extending along the metallization layers tapers at a different rate than a second portion of the sidewalls extending along the semiconductive substrate vertically adjacent to the first portion.

3. The semiconductor device of claim 2, wherein the taper of a third portion of the sidewalls extending along the semiconductive substrate adjacent to the back surface of the semiconductive substrate tapers at a different rate than the second portion of the sidewalls.

4. The semiconductor device of claim 2, wherein the taper of the first portion tapers at a greater rate than the taper of the second portion.

5. The semiconductor device of claim 2, wherein the taper of the first portion tapers at a lesser rate than the taper of the second portion.

6. The semiconductor device of claim 1, wherein at least one of the opposing sidewalls is disposed laterally spaced from a second semiconductor chip, wherein a dielectric fill occupies the spacing between the first semiconductor chip and the second semiconductor chip.

7. The semiconductor device of claim 1, wherein a radius of junction between the at least one of the opposing sidewalls and the front surface of the first semiconductor chip exceeds about one nm.

8. The semiconductor device of claim 1, further comprising:
a second semiconductor chip stacked over the first semiconductor chip, wherein the opposing sidewalls of the first semiconductor chip exhibit congruent taper to the taper of the first semiconductor chip.

9. The semiconductor device of claim 8, further comprising:
a first seal ring of the first semiconductor chip laterally bounding a second seal ring of the second semiconductor chip.

10. The semiconductor device of claim 8, further comprising:
a second seal ring of the second semiconductor extending laterally beyond a first seal ring of the first semiconductor chip.

11. A semiconductor device, comprising:
a substrate;
a first semiconductor chip;
a second semiconductor chip bonded with the first semiconductor chip;
a dielectric fill encapsulating sidewalls of the bonded first and second semiconductor chips, wherein:
the first semiconductor chip is vertically closer to the substrate than the second semiconductor chip, and
the first semiconductor chip is laterally closer to an edge of the dielectric fill than the first second semiconductor chip; and
a third semiconductor chip laterally spaced from the sidewalls of the bonded first and second semiconductor chips.

12. The semiconductor device of claim 11, wherein:
the substrate is an interposer configured to couple the first semiconductor chip and the second semiconductor chip with a printed circuit board assembly.

13. The semiconductor device of claim 11, wherein:
the dielectric fill terminates along a lateral sidewall between the first semiconductor chip and the third semiconductor chip, at a distance of less than 100 μm from a sidewall of the first semiconductor chip.

14. The semiconductor device of claim 11, wherein:
the third semiconductor chip is a memory device operatively coupled with a processor of the first semiconductor chip or the second semiconductor chip through the substrate.

15. The semiconductor device of claim 11, wherein:
the first semiconductor chip and the second semiconductor chip comprise corresponding first and second seal rings, wherein the first seal ring laterally bounds the second seal ring.

16. The semiconductor device of claim 11, wherein:
the first semiconductor chip and the second semiconductor chip comprise corresponding first and second seal rings, wherein the first seal ring does not laterally bound the second seal ring.

17. A semiconductor device, comprising:
a first semiconductor chip having a first surface and a second surface;
a second semiconductor chip having a first surface bonded with the second surface of the first semiconductor chip;
a dummy chip having a first surface bonded with the second surface of the first semiconductor chip, the dummy chip being laterally spaced from the second semiconductor chip, and
a dielectric fill encapsulating sidewalls of the first semiconductor chip, the second semiconductor chip, and the dummy chip,
wherein opposing sidewalls of the first semiconductor chip, the second semiconductor chip, and the dummy chip exhibit taper to reduce a lateral dimension of the respective sidewalls extending along a direction extending between and perpendicular to the first and second surfaces of the first semiconductor chip.

18. The semiconductor device of claim 17, wherein the first surfaces of the first semiconductor chip and the second semiconductor chip comprise active surfaces coupled with a plurality of metallization layers.

19. The semiconductor device of claim 17, wherein a rate of taper of the first semiconductor chip is equal to a rate of taper of the second semiconductor chip.

20. The semiconductor device of claim 19, wherein the equal rate of taper varies between sidewalls of:
an oxide portion of the first and second semiconductor chips; and
a substate portion of the first and second semiconductor chips.
